(19) United States
(12) Patent Application Publication
(10) Pub. No.: US 2026/0142626 A1
(43) Pub. Date: May 21, 2026

(54) METHOD AND SYSTEM TO IMPROVE SENSOR SIGNAL AMPLIFICATION PERFORMANCE

(71) Applicant: Shenzhen Litetrace Technologies CO., Ltd., Guangdong (CN)

(72) Inventor: Ming DENG, Guangdong (CN)

(73) Assignee: Shenzhen Litetrace Technologies CO., Ltd., Guangdong (CN)

(21) Appl. No.: 19/060,785

(22) Filed: Feb. 24, 2025

(30) Foreign Application Priority Data
Nov. 19, 2024 (CN) 202411654353.3

(51) Int. Cl. H03F 3/04; G01P 13/00

(52) U.S. Cl. CPC H03F 3/04; G01P 13/00

(57) ABSTRACT

A method to improve sensor signal amplification performance, comprising the following steps: S1: an equipment is powered on and initialized to enable a signal processor MCU to obtain an accurate bias reference voltage value; S2: a signal communication circuit between the sensor device and the amplifier device is connected to detect a motion signal; S3: the MCU compares an amplifier device output signal read with an accurate bias reference voltage obtained during initialization, and calculates a difference value or an accumulated difference value over a preset time. If the difference value or the accumulated difference value exceeds a set threshold, it is considered that a motion has been detected, and a corresponding operation is executed according to a preset way.

### CROSS-REFERENCE TO RELATED APPLICATION

This application claims the priority benefit of China application no. 202411654353.3, filed on Nov. 19, 2024. The entirety of the above-mentioned patent application is hereby incorporated by reference herein and made a part of this specification.

### Technical Field

The present invention is within the field of sensor technology, specifically relating to analog signal motion sensor and its signal amplification processing technology, as well as their applications in the fields of lighting control and smart building control. In particular, it involves a method and a system to improve sensor signal amplification performance.

### Description of Related Art

Motion sensors have a wide range of applications in the fields of lighting control and smart building control. For example, a function of turning on a light when someone is present and turning it off when someone leaves is enabled through motion detecting. Similarly, a function of turning on a HVAC system when someone is present and turning it off a when someone leaves is enabled through motion detecting. This enables automatic and smart control, providing users with a more comfortable and energy-saving environment.

Commonly used motion sensor devices include passive infrared sensors (PIR), microwave sensors, and ultrasonic sensors. These devices output weak electrical signals while detecting motions. Usually, in the motion control devices, analog signal amplification circuits are included to amplify and detect these electrical signals, facilitating subsequent judgment of whether actual motion has been detected.

Common circuits configured for amplifying motion signal consist of the following two design schemes:

### 1) A Direct Analog Signal Amplification Design Scheme

FIG. 1 illustrates a direct analog signal amplification design scheme. In FIG. 1, 1 represents a sensor device, 2 represents an amplifier device, 3 represents a voltage division circuit, and 4 represents a signal detection part. A signal output pin of the sensor device is connected to the amplifier device. When a motion is detected, a weak electrical signal is output. The amplifier device is capable of amplifying this weak electrical signal and superimposing it onto a bias reference voltage for output. The voltage divider circuit provides the bias reference voltage for the amplifier, which is usually enabled using two or more resistors. The signal detection part is configured to detect and confirm whether the amplified signal represents a motion. The detection method usually involves comparing a signal output from the amplifier with a designed reference bias voltage, and calculating a difference value or an accumulated difference value over a period of time. If the difference value or accumulated difference value exceeds a threshold, it is considered that a motion has been detected. The design of this part is usually implemented by a microprocessor and its peripheral circuits, or may be implemented by a set of hardware circuits. This scheme is a relatively common reference design. However, this scheme has the following issues that may affect the analog signal processing performance: a power supply voltage error: VCC is the power supply voltage, and the bias reference voltage is obtained from this power supply voltage division. If there is an error in the power supply voltage, the signal output from the amplifier will also have an error compared with the design, leading to a decline in subsequent signal processing performance; a voltage division circuit error: the voltage division circuit output is usually designed for voltage division with multiple resistors, and the precision of the resistors themselves will affect the accuracy of the voltage division, resulting in an error in the signal output from the amplifier compared with the design, which in turn causes a decline in subsequent signal processing performance; an error inherent in the amplifier device: the internal circuits of the amplifier may have certain individual differences, leading to an error in the amplified output signal compared with the design, which in turn causes a decline in subsequent signal processing performance.

### 2) An Analog Signal Amplification and Reference Voltage Detection Design Scheme

FIG. 2 illustrates an analog signal amplification and reference voltage detection design scheme. In FIG. 2, compared with FIG. 1, additional connecting wires are introduced, indicated as 5. These connecting wires simultaneously connect the bias reference voltage to both the amplifier and the signal detection part circuits. The signal detection part has been revised and optimized to compare the signal output from the amplifier with the actual reference bias voltage, and to calculate the difference or the accumulated difference over a period of time. If the difference or accumulated difference exceeds a threshold, it is considered that motion has been detected. Compared with the previous scheme, the analog signal amplification and reference voltage detection design scheme can effectively mitigate errors from the power supply voltage and the voltage division circuit, thereby enhancing the signal processing performance. However, this scheme still cannot avoid the errors inherent in the amplifier device.

### SUMMARY

As previously mentioned, these two common design schemes for analog signal amplification of motion devices cannot effectively mitigate errors, resulting in compromised performance in detecting motion signals. This can lead to limitations in product application, failing to meet a wider range of application scenarios, and may cause issues such as false detections. Therefore, there is an urgent need for a better and higher-performance design scheme.

Requirements and objectives of a new design scheme include: the design scheme should be simple and feasible, and may be implemented using general-purpose components, without increased costs significantly. It is capable of effectively mitigating errors related to power supply voltage, voltage division circuit, and amplifier device.

A purpose of the present invention is to provide a method and a system to improve sensor signal amplification performance, aiming at addressing the aforementioned technical issues.

The present invention is implemented as follows: a method to improve sensor signal amplification performance. A switching device is added between a sensor device and an amplifier device, and the switching device is communicatively connected to a signal processor MCU. The signal processor MCU controls the switching device to connect or disconnect the signal communication between the sensor device and the amplifier device by outputting a connection and disconnection command. A power terminal of the switching device is connected to a power supply VCC. The method to improve sensor signal amplification performance comprises the following steps:
S1. an equipment is powered on and initialized to enable the signal processor MCU to obtain an accurate bias reference voltage value; and
S2. the signal between the sensor device and the amplifier device is connected to detect a motion signal and provide it to the next step; and
S3. a signal processor MCU compares an amplifier device output signal read with an accurate bias reference voltage obtained during initialization, and calculates a difference value or an accumulated difference value over a preset time. If the difference value or accumulated difference value exceeds a set threshold, it is considered that a motion has been detected, and a corresponding operation is executed according to a preset way. If the difference value or accumulated difference value does not exceed a set threshold, it is necessary to return to the step S2.

The further technical scheme of the present invention is as follows: the step S1 further comprises the following steps:
S11. the signal processor MCU outputs a control disconnection command to a control terminal of the switching device, and the switching device executes the control command to cut off the communication between the amplifier device and the sensor device; and
S12. the signal processor MCU continuously reads the voltage output from the amplifier device and judge whether a fluctuation value in the voltage meet an error margin requirement. If met, a data read is considered acceptable, and an accurate bias reference voltage value is recorded for subsequent signal processing and application, and the step S2 MCU is executed continuously. If not met, the step S12 cycle detection is continued until the requirement is met.

The further technical scheme of the present invention is: in the step S12, the amplifier device is powered on to enter a stable working state, and the signal processor MCU continuously reads the readouts output from the amplifier device at an interval of several milliseconds and calculates a fluctuation range of the readouts. The fluctuation range of the readouts should be less than a certain scope.

The further technical scheme of the present invention is as follows: the step S2 further comprises the following steps:
S21. the signal processor MCU outputs a control command to a control terminal of the switching device, which executes the control command to connect the communication between the amplifier device and the sensor device. The amplifier device amplifies a signal transmitted from the sensor device; and
S22. the signal processor MCU continuously reads the voltage readouts output from the amplifier device.

The further technical scheme of the present invention is as follows: the step S3 further comprises the following steps:
S31. calculating a difference value or an accumulated different value between a voltage readout read and an accurate bias reference voltage value; and
S32. judging whether a difference value or an accumulated different value meets a motion demand. If met, it is considered that a motion has been detected, and a corresponding operation is executed. If not met, it is necessary to return the step S31.

The further technical scheme of the present invention is as follows: in the step S32, a difference value comparison method or an integral comparison method is used to judge whether a difference value or an accumulated difference value meets a motion demand.

The further technical scheme of the present invention is as follows: the signal processor MCU is equipped with a TLSR8250 Bluetooth chip, which integrates Bluetooth wireless transceiver function, features a 32M MCU, and comprises a built-in random access memory and flash memory.

Another purpose of the present invention is to provide a system to improve sensor signal amplification performance. A switching device is added between a sensor device and an amplifier device, and the switching device is communicatively connected to a signal processor MCU. The signal processor MCU controls the switching device to connect or disconnect the signal communication between the sensor device and the amplifier device by outputting a connection and disconnection command. A power terminal of the switching device is connected to a power supply VCC. The system to improve sensor signal amplification performance comprises
reference voltage acquisition module, configured for the signal processor MCU to obtain an accurate bias reference voltage value after the equipment is powered on and initialized; and
motion module, configured to connect a signal between sensor device and amplifier device, and detect a motion signal and provide it to a signal processing module; and
signal processing module, configured for the signal processor MCU to compare the amplifier device output signal read with the accurate bias reference voltage obtained during initialization, and calculate a difference value or an accumulated difference value over a preset time. If the difference value or accumulated difference value exceeds a set threshold, it is considered that a motion has been detected, and a corresponding operation is executed according to a preset way. If the difference value or accumulated difference value does not exceed a set threshold, it is necessary to return to the motion module.

The further technical scheme of the present invention is as follows: the reference voltage acquisition module further comprises
a switching device closing unit, configured for the signal processor MCU to output a control disconnection command to a control terminal of the switching device. The switching device executes the control command to cut off the communication between the amplifier device and the sensor device; and
voltage value acquisition unit, configured for the signal processor MCU to continuously read the voltage output from the amplifier device and judge whether a fluctuation value in the voltage meet an error margin requirement. If a data read meets the requirement, an accurate bias reference voltage value is recorded for subsequent signal processing and application, and the motion module is executed continuously. If not met, the voltage value acquisition unit cycle detection is continued until the requirement is met; and
in the voltage value acquisition unit, the amplifier device is powered on to enter a stable working state, and the signal processor MCU continuously reads the readouts output from the amplifier device at an interval of several milliseconds and calculates a fluctuation range of the readouts. The fluctuation range of the readouts should be less than a certain scope.

The further technical scheme of the present invention is as follows: the motion module comprises
motion unit, configured to detect a motion near the sensor device and output a detected signal to a subsequent unit; and
switching unit, configured for the signal processor MCU to control the connection and disconnection between the sensor device and the amplifier; and
signal amplification unit, configured for the signal processor MCU to receive a motion signal output from the sensor device after controlling the communication between the amplifier device and sensor device, and amplify the motion signal received;
the signal processing module comprises
voltage reading unit, configured for the signal processor MCU to continuously read the voltage readouts of an amplified motion signal output by the amplifier device; and
difference value calculation unit, configured to calculate a difference value or an accumulated different value between a voltage readout of a motion signal and an accurate bias reference voltage value; and
judgment comparison execution unit, configured to judge whether a difference value or an accumulated different value meets a motion demand. If met, it is considered that a motion has been detected, and a corresponding operation is executed. If not met, it is necessary to return to the difference value acquisition unit;
in the judgment comparison execution unit, a difference value comparison method or an integral comparison method is used to judge whether a difference value or an accumulated difference value meets a motion demand; and
the signal processor MCU is equipped with a TLSR8250 Bluetooth chip, which integrates Bluetooth wireless transceiver function, features a 32M MCU, and comprises a built-in random access memory and flash memory.

The beneficial effects of the present invention are as follows: this scheme is simple and clear, effectively mitigating errors from multiple sources and effectively improving signal processing accuracy. As an edge device in the Internet of Things, the sensor device has developed towards intelligence. The sensor device is equipped with a microprocessor, and the processing capabilities of the microprocessor can be fully utilized in the scheme of this application without causing a significant increase in costs. This application can effectively avoid the impacts of errors from power supplies, resistors, and amplifiers, allowing for reduced precision requirements for these components in actual design and production. This not only lowers costs but also reduces the need for stringent consistency screening of components and related expenses, thereby helping to decrease overall costs in practical applications. The improvement in the accuracy of motion analog signal processing enables the sensor device to more accurately detect motions, even at greater distances and for smaller movements, while effectively reducing the motion error rate and missed detection rate. This broadens the application range and scenarios for the sensor device, facilitating the promotion of smart lighting and smart building control application.

### BRIEF DESCRIPTION OF THE DRAWING

FIG. 1 is a block diagram of a direct analog signal amplification design scheme provided by an embodiment of the present invention.

FIG. 2 is a block diagram of an analog signal amplification and reference voltage detection design scheme provided by an embodiment of the present invention.

FIG. 3 is a block diagram of a design scheme for improving sensor signal amplification processing provided by an embodiment of the present invention.

FIG. 4 is a flow chart of a method to improve sensor signal amplification performance provided by an embodiment of the present invention.

FIG. 5 is a flow chart of an accurate bias reference voltage value acquisition provided by an embodiment of the present invention.

FIG. 6 is a flow chart of motion detection provided by an embodiment of the present invention.

FIG. 7 is an external view of the front and back of a Bluetooth smart lighting sensor shell and a circuit board provided by an embodiment of the present invention.

FIG. 8 is a schematic diagram of a smart lamp equipped with a smart lighting sensor provided by an embodiment of the present invention.

FIG. 9 is a test results diagram of the sensor A provided by an embodiment of the present invention.

FIG. 10 is a test results diagram of the sensor B provided by an embodiment of the present invention.

FIG. 11 is a test results diagram of the sensor C provided by an embodiment of the present invention.

### DESCRIPTION OF THE EMBODIMENTS

The embodiments of the present invention are described in detail as below, with examples illustrated in the drawings, where the same or similar reference numbers always indicate the same or similar elements or elements with the same or similar functions. The embodiments described below with reference to the drawings are exemplary and intended to explain the present invention, and should not be construed as a limitation on the present invention.

In the description of the present invention, it should be understood that orientation or position relationship indicated by the terms “length”, “width”, “up”, “down”, “front”, “rear”, “left”, “right”, “vertical”, “horizontal”, “top”, “bottom”, “inside”, “outside”, etc. are based on the orientation or position relationship as shown in the drawings. These terms are used solely for the convenience of describing the present invention and simplifying the description, and do not indicate or imply that the device or element referred to must have a specific orientation, or be constructed and operated in a specific orientation. Therefore, these terms should not be construed as limitations on the present invention. Additionally, in the description of the present invention, the term “multiple” means two or more, unless otherwise explicitly specified.

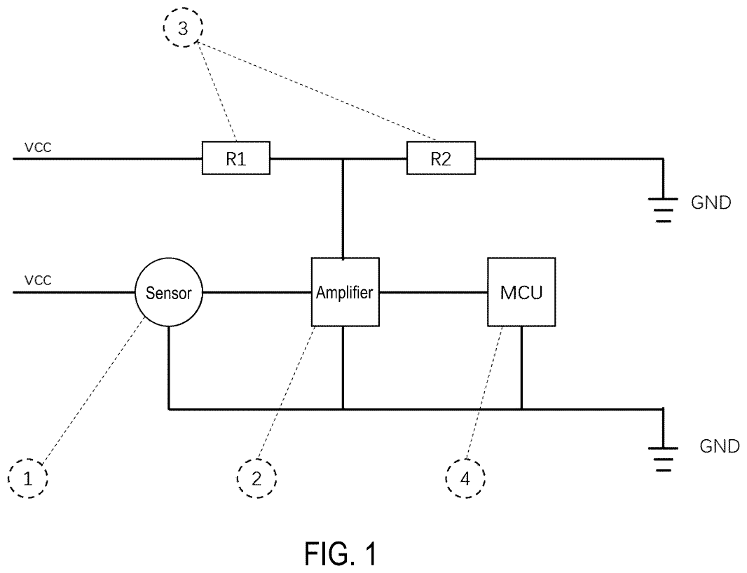

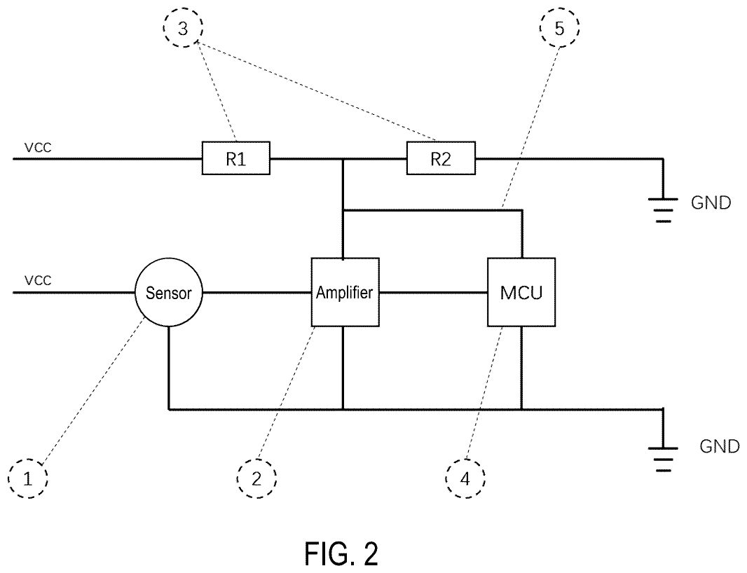

As shown in FIG. 1, a flow chart of a method to improve sensor signal amplification performance provided by the present invention, which is described in detail as follows:
a signal detection and judgment function is implemented through the signal processor MCU.
Step S1: an equipment is powered on and initialized to enable the signal processor MCU to obtain an accurate bias reference voltage value; after the equipment is powered on or initialized, the signal processor MCU first needs to obtain an accurate bias reference voltage. During the initialization (or reset) of the equipment, the signal output from the sensor to the amplifier is cut off, leading to an input pin of the amplifier to be in a low-level state. When the signal processor MCU is initialized, it detects an output voltage of the amplifier, which consists of an actual accurate bias reference voltage value after a power supply voltage error, voltage division circuit error, and an amplifier device error are accounted for. The signal processor MCU records this value for subsequent signal detection and judgment.
Step S2: the signal between the sensor device and the amplifier device is connected to detect a motion signal and provide it to the next step; the signal processor MCU outputs a control command to a control terminal of the switching device after obtaining an accurate bias reference voltage. The switching device executes the control command to connect the communication output/input circuit between the sensor and the amplifier, and start detecting the motion signal. The characteristics of the sensor are used to detect the signal, which are then transmitted to the amplifier for signal amplification. Meanwhile, the signal processor MCU continuously reads the voltage readout from the signal amplified by the amplifier and outputs the readout for application in the next process.
Step S3: a signal processor MCU compares an amplifier device output signal read with an accurate bias reference voltage obtained during initialization, and calculate a difference value or an accumulated difference value over a preset time. If the difference value or accumulated difference value exceeds a set threshold, it is considered that a motion has been detected, and a corresponding operation is executed according to a preset way. If the difference value or accumulated difference value does not exceed a set threshold, it is necessary to return to the step S2. The signal processor MCU then continues to detect a motion signal, and executes a corresponding operation according to a preset way when a motion is successfully detected. During detection, the signal processor MCU compares the amplifier output signal read with the accurate reference bias voltage obtained during initialization, and calculate a difference value or an accumulated difference value over a period of time. If the difference value or accumulated difference value exceeds a threshold, it is considered that a motion has been detected.

According to the requirements and objectives of the schemes, the design requirements of the present invention are as follows:
a signal detection and judgment function is implemented through the signal processor MCU; and
during the initialization (or reset) of the equipment, the signal output from the sensor to the amplifier is cut off, leading to an input pin of the amplifier to be in a low-level state; and
when the signal processor MCU is initialized, it detects an output voltage of the amplifier, which consists of an actual accurate bias reference voltage value after a power supply voltage error, voltage division circuit error, and an amplifier device error are accounted for. The signal processor MCU records this value for subsequent signal detection and judgment.

After the signal processor MCU completes initialization and reads the accurate bias reference voltage, the signal output/input circuit between the sensor and the amplifier is connected to begin detecting a motion signal. During detection, the signal processor MCU compares the amplifier output signal read with the accurate reference bias voltage obtained during initialization, and calculate a difference value or an accumulated difference value over a period of time. If the difference value or accumulated difference value exceeds a threshold, it is considered that a motion has been detected.

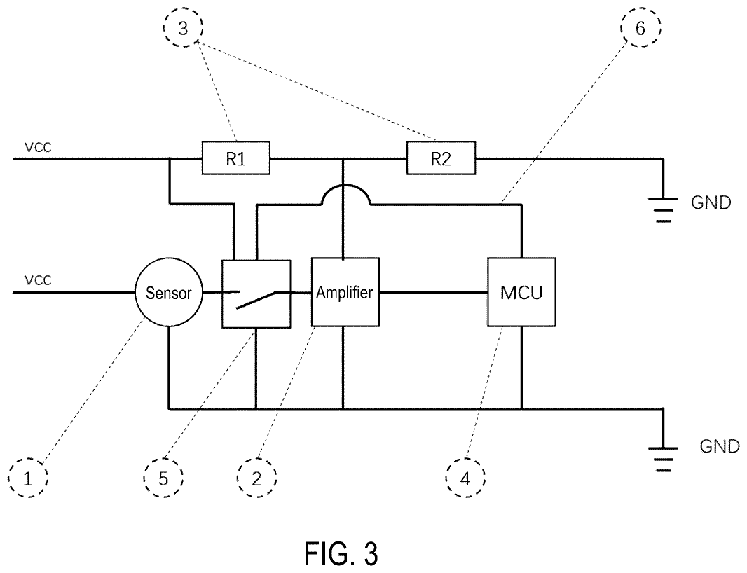

As shown in FIG. 3, this is the improved analog signal amplification processing design scheme of this application. It includes the following components:
component 1 is a sensor device. A signal output pin of the device is connected to a subsequent processing circuit. When the sensor detects a motion, it will output a weak electrical signal; and
component 2 is an amplifier device. The amplifier device can amplify a weak electrical signal and superimpose it onto a bias reference voltage for output; and
component 3 is a voltage division circuit that provides a bias reference voltage for an amplifier, which is usually implemented using two or more resistors.
component 4 is a signal detection part, which is used to detect and confirm whether an amplified signal represents a motion. This part of the circuit consists of a signal processing MCU and its peripheral circuits. A specific detection method will be explained in detail in a subsequent processing flow.
component 5 is a switching device. The signal processing MCU can control the connection and closing of this device. When this device is connected, a signal from a sensor can be directly connected and output to an amplifier. When this device is closed, a output signal from the sensor is cut off, and an input pin of the amplifier will remain in a low-level input state. In certain design applications, the switching device is enabled or should be placed before the installation of the sensor device.
component 6 is a control circuit of the signal processing MCU for controlling component 5. It is usually connected to a control pin of a switching device from a general-purpose input/output (GPIO) pin of the signal processing MCU. The signal processing MCU controls the connection and closing states of the switching device by setting high and low levels on this GPIO pin.

### An Overall Processing Flow

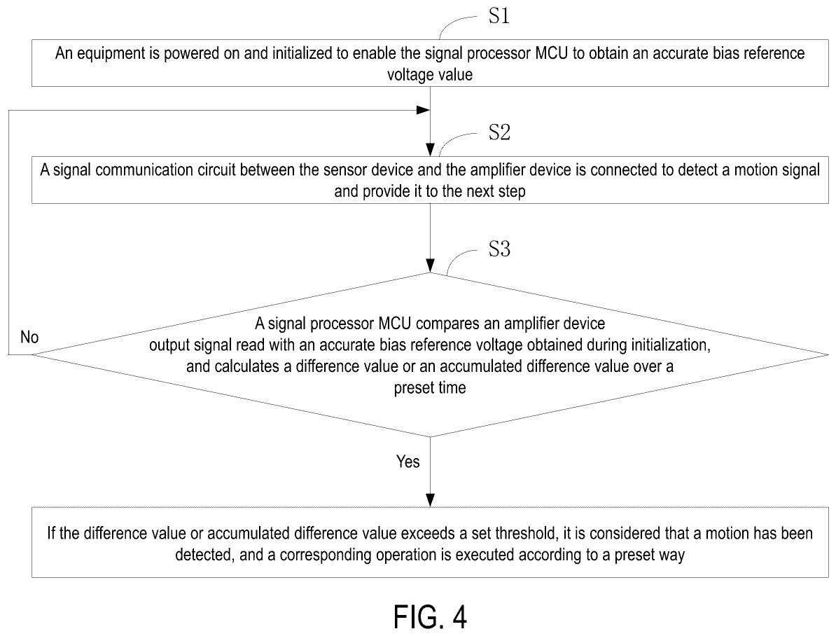

As shown in FIG. 4, an overall processing flow chart is presented.

After the equipment is powered on or initialized, the signal processor MCU first needs to obtain an accurate bias reference voltage.

The signal processor MCU then continues to detect a motion signal, and executes a corresponding operation according to a preset way when a motion is successfully detected.

An accurate bias reference voltage value acquisition flow

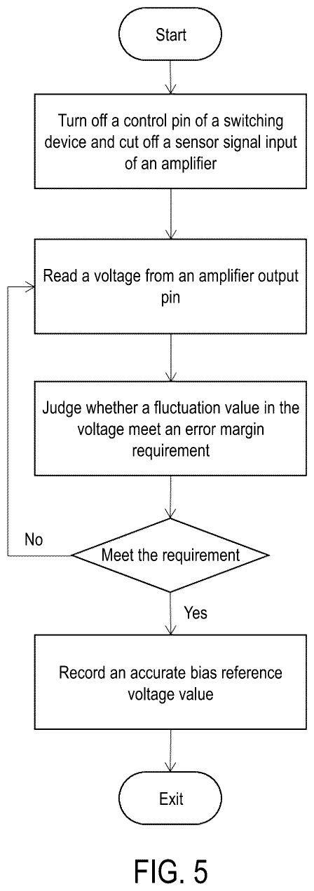

As shown in FIG. 5, a flow chart of an accurate bias reference voltage value acquisition is presented

The signal processing MCU controls the closing of a switching device through a GPIO pin, and cuts off a sensor signal input to an amplifier.

The signal processing MCU continuously reads a voltage from an amplifier output pin.

The signal processing MCU judges whether a fluctuation value in the voltage meet an error margin requirement. The judgment of the error margin can be confirmed by considering the following factors:
a typical power-on initialization time for an amplifier. Usually, during the power-on, an amplifier require milliseconds to seconds to initialize and reach a stable working state. Therefore, the signal processor MCU needs to wait for several seconds to avoid an unstable readout during the initialization period of an amplifier.

An amplifier output readout should be continuously read at an interval of several milliseconds, and a fluctuation range of a readout should be calculated. Once an amplifier is operating stably, a fluctuation range of a readout should be less than a certain threshold.

If a read data meets a requirement, then it is necessary to record this accurate bias reference voltage value for subsequent signal processing and application, and exit this process.

### A Motion Detection Flow

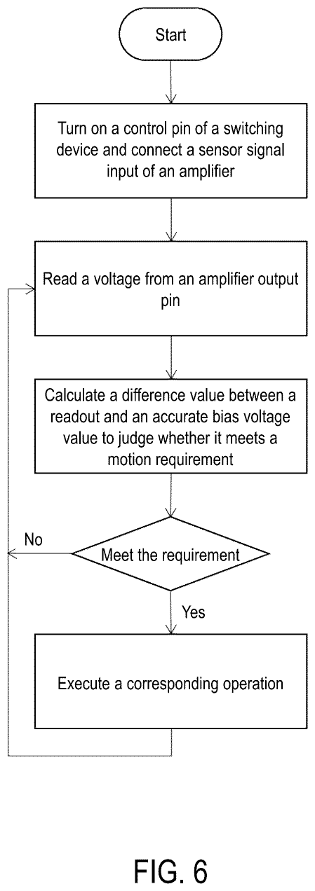

As shown in FIG. 6, a motion detection flow chart is presented.

The signal processing MCU controls the closing of a switching device through a GPIO pin, and cuts off a sensor signal input to an amplifier.

The signal processing MCU continuously reads a voltage from an amplifier output pin.

The signal processing MCU judges whether a fluctuation value in the voltage meet an error margin requirement. The judgment of the error margin can be confirmed by considering the following factors:
a typical power-on initialization time for an amplifier. Usually, during the power-on, an amplifier require milliseconds to seconds to initialize and reach a stable working state. Therefore, the signal processor MCU needs to wait for several seconds to avoid an unstable readout during the initialization period of an amplifier.

An amplifier output readout should be continuously read at an interval of several milliseconds, and a fluctuation range of a readout should be calculated. Once an amplifier is operating stably, a fluctuation range of a readout should be less than a certain threshold.

If a read data meets a requirement, then it is necessary to record this accurate bias reference voltage value for subsequent signal processing and application, and exit this process.

From the above scheme illustration, it can be seen that the improved motion sensor analog signal amplification processing design scheme offered by this patent of the present invention has several distinct advantages:
this scheme is simple and clear, effectively mitigating errors from multiple sources and effectively improving signal processing accuracy.

As an edge device in the Internet of Things, the sensor device has developed towards intelligence. The sensor device is equipped with a microprocessor, and the processing capabilities of the microprocessor can be fully utilized in the scheme of the present invention without causing a significant increase in costs.

This scheme can effectively avoid the impacts of errors from power supplies, resistors, and amplifiers, allowing for reduced precision requirements for these components in actual design and production. This not only lowers costs but also reduces the need for stringent consistency screening of components and related expenses, thereby helping to decrease overall costs in practical applications.

The improvement in the accuracy of motion analog signal processing enables the sensor device to more accurately detect motions, even at greater distances and for smaller movements, while effectively reducing the motion error rate and missed detection rate. This broadens the application range and scenarios for the sensor device, facilitating the promotion of smart lighting and smart building control application.

According to the technical scheme of this patent of the present invention, in the embodiment, a Telink TLSR8250 Bluetooth chip is configured as a microprocessor chip. This chip integrates Bluetooth wireless transceiver function, features a 32M MCU, and comprises a built-in random access memory and flash memory. This chip supports BLE MESH wireless communication technology, allowing up to 255 devices to be online simultaneously within a network. It is one of the preferred schemes for wireless smart devices and has been widely applied in the market.

A passive infrared (PIR) device is configured as a motion sensor device. The PIR device, paired with an appropriate Fresnel lens, can detect a slight change in infrared radiation emitted by a human body temperature during motion. It is configured to detect whether there is any motion within the field of view.

A designed sensor device is powered by DC 12V power supply. It provides a 0-10V dimming output terminal for controlling the on/off and brightness of a lighting lamp.

During the evaluation of the scheme, if a motion is detected, a lamp will be turned on and dimmed to the maximum brightness for 2 seconds. If no motion is detected, a lamp will be turned off.

### A Bluetooth Smart Lighting Sensor

In this embodiment, a Bluetooth smart lighting sensor is designed with a Telink TLSR8250 Bluetooth chip as a main chip, and powered by a DC 12V power supply. It comprises a PIR motion sensor, and controls a lamp through a 0-10V dimming output.

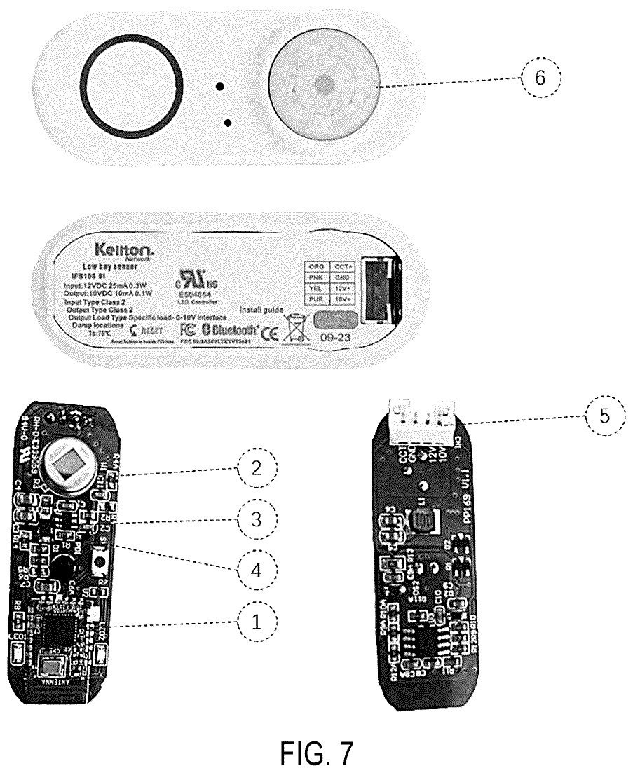

The controller appearance and the PCBA is shown in FIG. 7:

As shown in FIG. 7, this Bluetooth smart lighting sensor comprises the following components:
component 1 is a TLSR8250 Bluetooth chip, comprising Bluetooth transceiver and communication software, and sensor control software; and
component 2 is a PIR passive infrared motion device; and
component 3 is an amplifier device; and
component 4 is a switching control device; and
component 5 is an interface, comprising a DC 12V power input terminal and a 0-10V dimming output terminal; and
component 6 is a Fresnel lens of a PIR passive infrared motion device.

Other components on a circuit board and their functions are unrelated to this patent of the present invention and do not affect the functionality and effectiveness of this patent of the present invention; therefore, they are not described in the Specification.

A smart lamp equipped with a Bluetooth smart lighting sensor

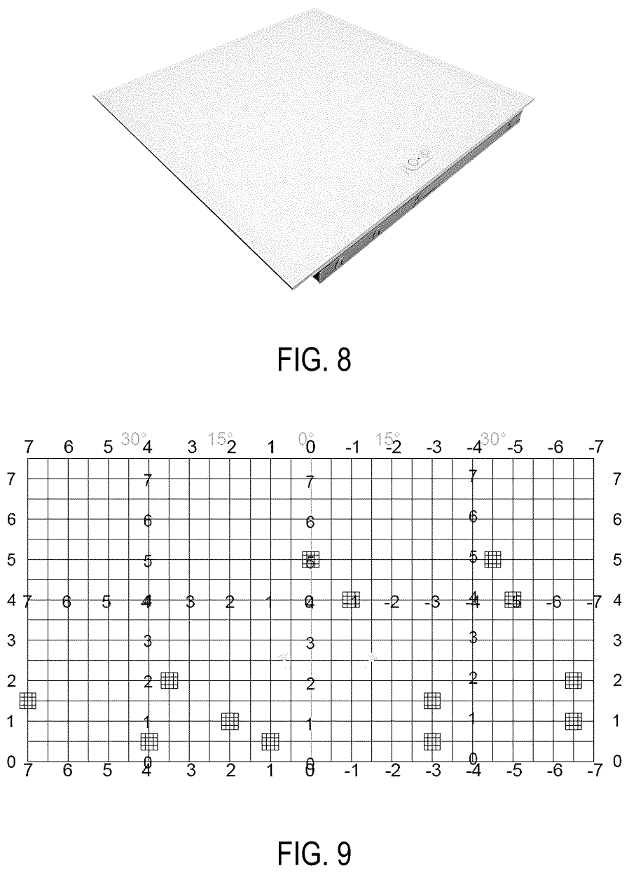

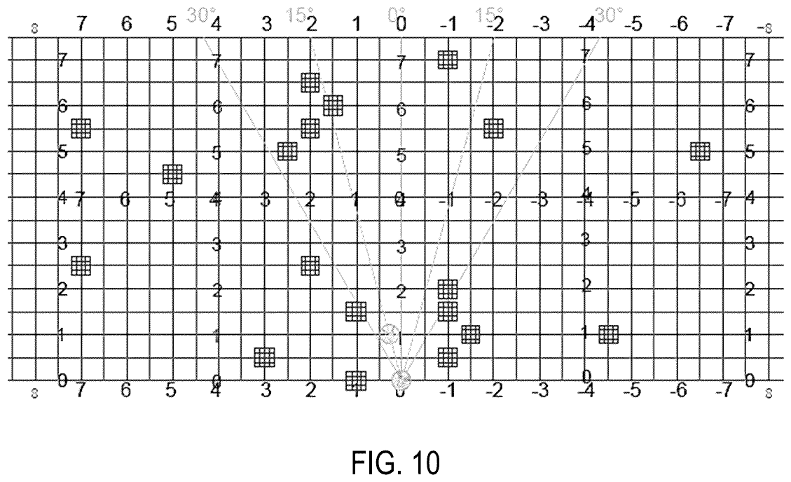

In this embodiment, a smart lamp are used, and a Bluetooth smart lighting sensor is installed. The smart lamp is equipped with a DC12V power output interface and a 0-10V dimming input interface, and a mounting position for the Bluetooth smart lighting sensor is reserved. They can work together with the Bluetooth smart lighting sensor to turn on, turn off, or dim the lamp. As shown in FIG. 8, the specific design and functions of the smart lamp are unrelated to this patent of the present invention and do not affect the functionality and effectiveness of this patent of the present invention; therefore, they are not described in the Specification.

### Test Results Evaluation

### Test Method

In an embodiment, a commonly used motion test method in the industry is used to test a motion performance in different design schemes. A brief illustration of the test method is as follows:
a lamp is installed at different heights, usually including 3 meters, 6 meters, 12 meters, etc.; and
a square grid with a center directly below a motion sensor is drawn on the ground, extending 0.5 meters in length; and
Under the condition of keeping a test site from interference, a tester walks from left to right and then from right to left, gradually approaching a sensor installation position at a normal walking speed, records a position where the sensor detects motion, and marks these sensing points on a coordinate graph; and
each time a motion is detected, the lamp will turn on. At this point, the tester needs to stop and wait for the lamp to turn off before continuing the test.

### Comparison Standards for Test Performance

According to the above test method, tests are conducted on the following sensors: a motion sensor comprising a direct analog signal amplification design scheme (sensor A), a motion sensor comprising an analog signal amplification and reference voltage detection design scheme (sensor B), and a Bluetooth smart lighting sensor comprising this patent of the present invention (sensor C).

Under the same installation heights and test conditions, the more sensing points detected for motions and the wider the coverage of these sensing points, the better the sensing performance of the sensor.

### Test Results

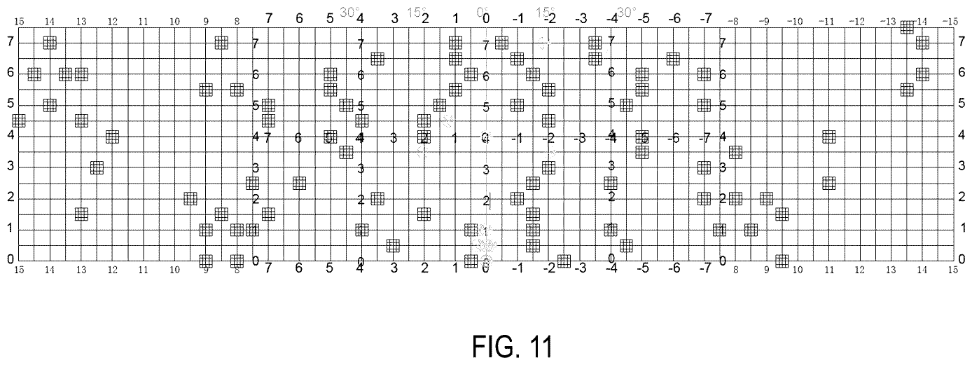

As shown in FIG. 9˜FIG. 11, the test results for the three sensors are presented.

### Test Results Evaluation

From the above test result diagrams, it can be seen that the motion performance of sensor B is slightly better than that of sensor A. The motion performance of sensor C far exceeds that of both sensor B and sensor A.

The test results indicate that the scheme of this patent of the present invention is practical and fully meets the design requirements and objectives, demonstrating excellent market and technical feasibility.

Another purpose of the present invention is to provide a system to improve sensor signal amplification performance. A switching device is added between a sensor device and an amplifier device, and the switching device is communicatively connected to a signal processor MCU. The signal processor MCU controls the switching device to connect or disconnect the signal communication between the sensor device and the amplifier device by outputting a connection and disconnection command. A power terminal of the switching device is connected to a power supply VCC. The system to improve sensor signal amplification performance comprises
reference voltage acquisition module, configured for the equipment to initialize the signal processor MCU to obtain an accurate bias reference voltage value after being powered on; and
motion module, configured to connect a signal between sensor device and amplifier device, and detect a motion signal and provide it to a signal processing module; and
signal processing module, configured for the signal processor MCU to compare the amplifier device output signal read with the accurate bias reference voltage obtained during initialization, and calculate a difference value or an accumulated difference value over a preset time. If the difference value or accumulated difference value exceeds a set threshold, it is considered that a motion has been detected, and a corresponding operation is executed according to a preset way. If the difference value or accumulated difference value does not exceed a set threshold, it is necessary to return to the motion module.

The reference voltage acquisition module further comprises
a switching device closing unit, configured for the signal processor MCU to output a control disconnection command to a control terminal of the switching device. The switching device executes the control command to disconnect the communication between the amplifier device and the sensor device; and
voltage value acquisition unit, configured for the signal processor MCU to continuously read the voltage output from the amplifier device and judge whether a fluctuation value in the voltage meet an error margin requirement. If a data read meets the requirement, an accurate bias reference voltage value is recorded for subsequent signal processing and application, and the motion module is executed continuously. If not met, the voltage value acquisition unit cycle detection is continued until the requirement is met; and
in the voltage value acquisition unit, the amplifier device is powered on to enter a stable working state, and the signal processor MCU continuously reads the readouts output from the amplifier device at an interval of several milliseconds and calculates a fluctuation range of the readouts. The fluctuation range of the readouts should be less than a certain scope.

The motion module comprises
motion unit, configured to detect a motion near the sensor device and output a detected signal to a subsequent unit; and
switching unit, configured for the signal processor MCU to control the connection and disconnection between the sensor device and the amplifier; and
signal amplification unit, configured for the signal processor MCU to receive a motion signal output from the sensor device after controlling the communication between the amplifier device and sensor device, and amplify the motion signal received;
the signal processing module comprises
voltage reading unit, configured for the signal processor MCU to continuously read the voltage readouts of an amplified motion signal output by the amplifier device; and
difference value calculation unit, configured to calculate a difference value or an accumulated different value between a voltage readout of a motion signal and an accurate bias reference voltage value; and
judgment comparison execution unit, configured to judge whether a difference value or an accumulated different value meets a motion demand. If met, it is considered that a motion has been detected, and a corresponding operation is executed. If not met, it is necessary to return to the difference value acquisition unit;
in the judgment comparison execution unit, a difference value comparison method or an integral comparison method is used to judge whether a difference value or an accumulated difference value meets a motion demand; and
the signal processor MCU is equipped with TLSR8250 Bluetooth chip, which integrates Bluetooth wireless transceiver function, features a 32M MCU, and comprises a built-in random access memory and flash memory.

The above description is only a preferred embodiment of the present invention and is not intended to limit the invention. Any modifications, equivalent substitutions, and improvements made within the spirit and principles of the present invention should be included within the protection scope of the present invention.

What is claimed is:

1. A method to improve sensor signal amplification performance, wherein a switching device is added between a sensor device and an amplifier device, and the switching device is communicatively connected to a signal processor MCU, wherein the signal processor MCU controls the switching device to connect or disconnect the signal communication between the sensor device and the amplifier device by outputting a connection and disconnection command, wherein a power terminal of the switching device is connected to a power supply VCC, and the method to improve the sensor signal amplification performance comprises the following steps:
step S1: powering on and initializing an equipment to enable the signal processor MCU to obtain an accurate bias reference voltage value;
step S2: connecting a signal communication circuit between the sensor device and the amplifier device to detect a motion signal and providing the motion signal to the next step; and
step S3: using the signal processor MCU to compare an amplifier device output signal read with an accurate bias reference voltage obtained during initialization, and using the signal processor MCU to calculate a difference value or an accumulated difference value over a preset time, wherein if the difference value or accumulated difference value exceeds a set threshold, it is considered that a motion has been detected, and a corresponding operation is executed according to a preset way, wherein if the difference value or accumulated difference value does not exceed a set threshold, returning to the step S2.

2. The method to improve the sensor signal amplification performance according to claim 1, wherein the step S1 further comprises the following steps:
step S11: using the signal processor MCU to output a control disconnection command to a control terminal of the switching device, and using the switching device to execute the control command to cut off the communication between the amplifier device and the sensor device; and
step S12: using the signal processor MCU to continuously read the voltage output from the amplifier device and using the signal processor MCU to judge whether a fluctuation value in the voltage meets an error margin requirement, wherein if the fluctuation value in the voltage meets the error margin requirement, a data read is considered acceptable, and an accurate bias reference voltage value is recorded for subsequent signal processing and application, and the step S12 is executed continuously by the signal processor MCU, wherein if the fluctuation value in the voltage does not meet the error margin requirement, the step S12 is continued until the fluctuation value in the voltage meets the error margin requirement.

3. The method to improve the sensor signal amplification performance according to claim 2, in the step S12, the amplifier device is powered on to enter a stable working state, and the signal processor MCU continuously reads the readouts output from the amplifier device at an interval of several milliseconds and calculates a fluctuation range of the readouts, wherein the fluctuation range of the readouts should be less than a certain scope.

4. The method to improve the sensor signal amplification performance according to claim 3, wherein the step S2 comprises the following steps:
step S21: using the signal processor MCU to output a control command to a control terminal of the switching device, which executes the control command to connect the communication between the amplifier device and the sensor device, wherein the amplifier device amplifies a signal transmitted from the sensor device; and
step S22: using the signal processor MCU to continuously read the voltage readouts output from the amplifier device.

5. The method to improve the sensor signal amplification performance according to claim 4, wherein the step S3 comprises the following steps:
step S31: calculating a difference value or an accumulated different value between a voltage readout read and an accurate bias reference voltage value; and
step S32: judging whether the difference value or the accumulated different value meets a motion demand, wherein if the difference value or the accumulated different value meets the motion demand, it is considered that a motion has been detected, and a corresponding operation is executed, wherein if the difference value or the accumulated different value does not meet the motion demand, returning to the step S31.

6. The method to improve the sensor signal amplification performance according to claim 5, in the step S32, a difference value comparison method or an integral comparison method is used to judge whether the difference value or the accumulated difference value meets the motion demand.

7. The method to improve the sensor signal amplification performance according to claim 6, wherein the signal processor MCU is equipped with a Bluetooth chip, which integrates Bluetooth wireless transceiver function, features a 32M MCU, and comprises a built-in random access memory and a flash memory.

8. A system to improve sensor signal amplification performance, wherein a switching device is added between a sensor device and an amplifier device, and the switching device is communicatively connected to a signal processor MCU, wherein the signal processor MCU is configured to control the switching device to connect or disconnect the signal communication between the sensor device and the amplifier device by outputting a connection and disconnection command, wherein a power terminal of the switching device is connected to a power supply VCC, wherein the system to improve the sensor signal amplification performance comprises
a reference voltage acquisition module, configured for the signal processor MCU to obtain an accurate bias reference voltage value after the equipment is powered on and initialized;
a motion module, configured to connect a signal between sensor device and amplifier device, and detect a motion signal and provide it to a signal processing module; and
the signal processing module, configured for the signal processor MCU to compare the amplifier device output signal read with the accurate bias reference voltage obtained during initialization, and calculate a difference value or an accumulated difference value over a preset time, wherein if the difference value or the accumulated difference value exceeds a set threshold, it is considered that a motion has been detected, and a corresponding operation is executed according to a preset way.

9. The system to improve the sensor signal amplification performance according to claim 8, wherein the reference voltage acquisition module further comprises:
a switching device closing unit, configured for the signal processor MCU to output a control disconnection command to a control terminal of the switching device, wherein the switching device is configured to execute the control command to cut off the communication between the amplifier device and the sensor device; and
a voltage value acquisition unit, configured for the signal processor MCU to continuously read the voltage output from the amplifier device and judge whether a fluctuation value in the voltage meets an error margin requirement, wherein if the fluctuation value in the voltage meets the error margin requirement, an accurate bias reference voltage value is recorded for subsequent signal processing and application, and the motion module is executed continuously, wherein if the fluctuation value in the voltage does not meet the error margin requirement, the voltage value acquisition unit cycle detection is continued until the fluctuation value in the voltage meets the error margin requirement;
wherein in the voltage value acquisition unit, the amplifier device is powered on to enter a stable working state, and the signal processor MCU continuously reads the readouts output from the amplifier device at an interval of several milliseconds and calculates a fluctuation range of the readouts, wherein the fluctuation range of the readouts is less than a certain scope.

10. The system to improve the sensor signal amplification performance according to claim 9, wherein the motion module comprises:
a motion unit, configured to detect a motion near the sensor device and output a detected signal to a subsequent unit;
a switching unit, configured for the signal processor MCU to control the connection and disconnection between the sensor device and the amplifier; and
a signal amplification unit, configured for the signal processor MCU to receive a motion signal output from the sensor device after controlling the communication between the amplifier device and sensor device, and to amplify a received motion signal;
wherein the signal processing module comprises:
a voltage reading unit, configured for the signal processor MCU to continuously read the voltage readouts of an amplified motion signal output by the amplifier device;
a difference value calculation unit, configured to calculate a difference value or an accumulated different value between a voltage readout of a motion signal and an accurate bias reference voltage value; and
a judgment comparison execution unit, configured to judge whether the difference value or the accumulated different value meets a motion demand, wherein if the difference value or the accumulated different value meets the motion demand, it is considered that a motion has been detected, and a corresponding operation is executed, wherein if the difference value or the accumulated different value does not meet the motion demand, it is necessary to return to a difference value acquisition unit;
wherein in the judgment comparison execution unit, a difference value comparison method or an integral comparison method is used to judge whether the difference value or the accumulated difference value meets the motion demand; and
wherein the signal processor MCU is equipped with a Bluetooth chip, which integrates Bluetooth wireless transceiver function, features a 32M MCU, and comprises a built-in random access memory and a flash memory.
